(19) United States
(12) Patent Application Publication
(10) Pub. No.: US 2010/0078621 A1
(43) Pub. Date: Apr. 1, 2010

(54) METHOD TO REDUCE RESET CURRENT OF PCM USING STRESS LINER LAYERS

(76) Inventors: Mathew J. Breitwisch, Yorktown Heights, NY (US); Eric A. Joseph, White Plains, NY (US); Chung H. Lam, Peekskill, NY (US); Bipin Rajendran, White Plains, NY (US); Alejandro G. Schrott, New York, NY (US)

Correspondence Address: LAW OFFICE OF IDO TUCHMAN (YOR), ECM #72212, PO Box 4668, New York, NY, 10163-4668, US

(21) Appl. No.: 12/243,809

(22) Filed: Oct. 1, 2008

(51) Int. Cl. H01L 45/00

(52) U.S. Cl. 257/4; 438/102; 257/E45.002

(57) ABSTRACT

A memory cell structure and method for forming the same. The method includes forming a via within a dielectric layer. The via is formed over the center of an electrically conducting bottom electrode. The method includes depositing a stress liner along at least one sidewall of the via. The stress liner imparting stress on material proximate the stress liner. In one embodiment, the stress liner provides a stress in the range of 500 to 5000 MPa on the material enclosed within its volume. The method includes depositing phase change material within the via and the volume enclosed by the stress liner. The method also includes forming an electrically conducting top electrode above the phase change material.

### BACKGROUND OF THE INVENTION

1. Field Of The Invention

The present invention relates to memory cell structures for phase change memory, and methods for forming the same.

2. Description of Background

There are two major groups in computer memory: non-volatile memory and volatile memory. Constant input of energy in order to retain information is not necessary in non-volatile memory but is required in the volatile memory. Examples of non-volatile memory devices are Read Only Memory (ROM), Flash Electrical Erasable Read Only Memory, Ferroelectric Random Access Memory, Magnetic Random Access Memory (MRAM), and Phase Change Memory (PCM); non-volatile memory devices being memory in which the state of the memory elements can be retained for days to decades without power consumption. Examples of volatile memory devices include Dynamic Random Access Memory (DRAM) and Static Random Access Memory (SRAM); where DRAM requires the memory element to be constantly refreshed while SRAM requires a constant supply of energy to maintain the state of the memory element. The present invention is directed to phase change memory. In phase change memory, information is stored in materials that can be manipulated into different phases. Each of these phases exhibit different electrical properties which can be used for storing information. The amorphous and crystalline phases are typically two phases used for bit storage (1's and 0's) since they have detectable differences in electrical resistance. Specifically, the amorphous phase has a higher resistance than the crystalline phase.

Chalcogenides are a group of materials commonly utilized as phase change material. This group of materials contain a chalcogen (Periodic Table Group 16/VIA) and another element. Selenium (Se) and tellurium (Te) are the two most common semiconductors in the group used to produce a chalcogenide when creating a phase change memory cell. An example of this would be Ge₂Sb₂Te₅ (GST), SbTe, and In₂Se₃.

One issue with phase change memory is the energy required to melt the phase change material. A high melting point requires more energy to melt the phase change material. Additionally, the high melting point creates a smaller “melt region” in the phase change material. The smaller melt region makes it more difficult to detect resistive changes in the phase change material. Thus, it is desirable to devise a solution to reduce the melting point of the phase change material and increase the size of the melt region.

### SUMMARY OF THE INVENTION

One aspect of the invention is a method for forming a memory cell structure. The method includes forming a bottom electrode within a substrate, with the bottom electrode being electrically conducting. The method also includes depositing a dielectric layer over the bottom electrode. The dielectric layer is electrically insulating. The method is also comprised of forming a via within the dielectric layer and substantially over the center of the bottom electrode. The via includes at least one sidewall. The method includes depositing a stress liner along at least one sidewall of the via. The stress liner imparts stress on material proximate to the stress liner. The method also includes depositing a phase change material within the via and within a volume enclosed by the stress liner. Additionally, the method includes forming a top electrode above the phase change material. The top electrode is also electrically conducting.

Another aspect of the invention is a memory cell structure. The memory cell structure is comprised of an electrically conducting bottom electrode. The memory cell structure is also comprised of a stress liner forming a via above the bottom electrode. The stress liner imparts stress on material within the via. The memory cell structure is also comprised of a phase change material disposed within the via and within a volume enclosed by the stress liner. Additionally, the memory cell structure includes an electrically conducting top electrode disposed above the phase change material.

### BRIEF DESCRIPTION OF THE DRAWINGS

The subject matter which is regarded as the invention is particularly pointed out and distinctly claimed in the claims at the conclusion of the specification. The foregoing and other objects, features, and advantages of the invention are apparent from the following detailed description taken in conjunction with the accompanying drawings in which:

FIG. 1 illustrates a substrate, a bottom electrode, and a dielectric layer with a via.

FIG. 2 illustrates stress liner material deposition.

FIG. 3 illustrates stress liner formation.

FIG. 4 illustrates phase change material deposition.

FIG. 5 illustrates top electrode formation.

FIG. 6 illustrates a substrate, a bottom electrode, a dielectric layer with a via, and an undercut.

FIG. 7 illustrates stress liner material deposition.

FIG. 8 illustrates stress liner formation.

FIG. 9 illustrates phase change material deposition.

FIG. 10 illustrates top electrode formation.

### DETAILED DESCRIPTION OF THE INVENTION

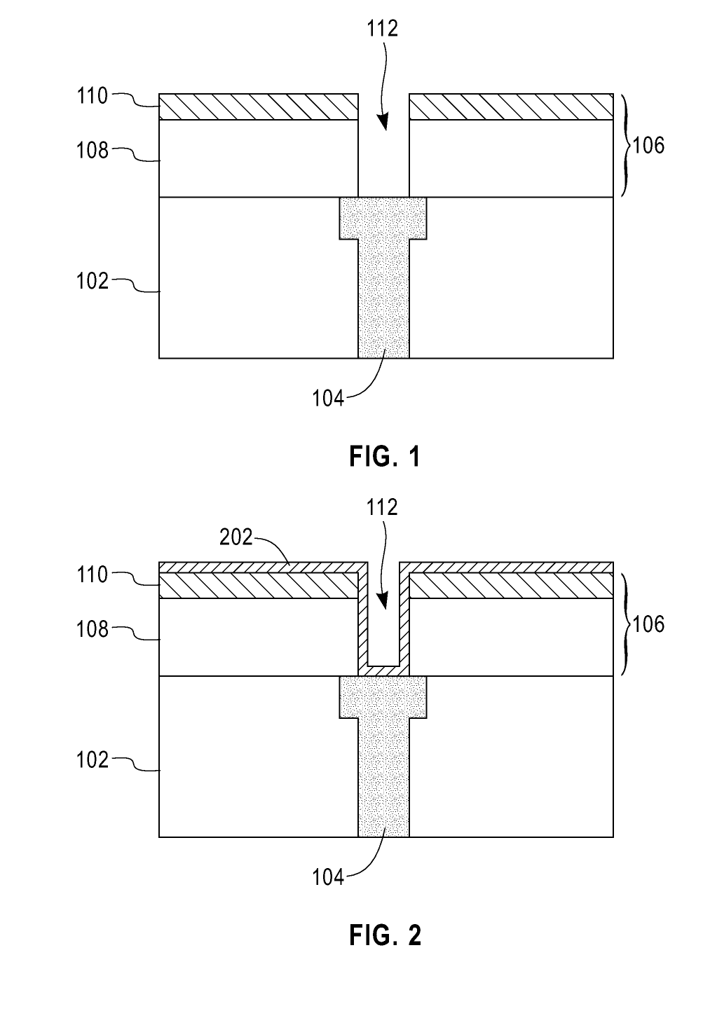

The present invention is described with reference to embodiments of the invention. Throughout the description of the invention reference is made to FIGS. 1-10.

As described below, an aspect of the present invention is a method for forming a memory cell structure for phase change memory. The method includes forming a via within a dielectric layer, where a stress liner is deposited along at least one sidewall of the via. The method also includes depositing a phase change material in the via. The stress liner imparts stress on the phase change material. The increased stress on the phase change material effectively lowers the melting point of the phase change material during phase change. Additionally, the lower melting point increases the size of the “melt region” (the volume of phase change material that undergoes phase change).

In a typical phase change memory configuration, the phase change material is used to store data bits. An example of such a phase change material is Germanium-Antimony-Tellurium (GST). The phase change material may be programmed to one of two states: a crystalline state or an amorphous state. The crystalline state may represent a stored “0” value and the amorphous state may represent a stored “1” value. In the crystalline state, the phase change material exhibits a relatively low resistance. On the other hand, in the amorphous state, the phase change material has a relatively high resistance.

In the phase change memory configuration, altering the phase change material's state requires heating the material to a melting point and then cooling the material to one of the possible states. A current passed through the phase change material creates ohmic heating and causes the phase change material to melt. Melting and gradually cooling down the phase change material allows time for the phase change material to form the crystalline state. Melting and abruptly cooling the phase change material quenches the phase change material into the amorphous state.

FIGS. 1-5 illustrate one embodiment of the method. FIG. 1 shows a substrate 102 and a bottom electrode 104 formed within the substrate 102 in accordance with one embodiment of the invention. In this particular embodiment of the invention, the substrate 102 is comprised of silicon and the bottom electrode 104 is comprised of an electrically conductive material. In one embodiment of the invention, the bottom electrode is comprised of Tungsten (W) or titanium-nitride (TiN). Those skilled in the art will recognize that a variety of methods can be utilized to form the bottom electrode 104 within the substrate 102, such as a reactive-ion etch (RIE) and sputter deposition.

A dielectric layer 106 is deposited above the bottom electrode 104 and the substrate 102. The dielectric layer 106 may be comprised of an insulating material, such as, but not limited to, silicon nitride (SiN) and silicon dioxide (SiO₂). In one embodiment of the invention, the dielectric layer 106 is comprised of at least two separately removable layers such that there is a bottom dielectric layer 108 and a top dielectric layer 110, as illustrated. Those skilled in the art will recognize that a variety of processes may be utilized for dielectric layer 106 deposition, such as chemical vapor deposition (CVD) and plasma-enhanced chemical vapor deposition (PECVD).

Also shown in FIG. 1 is a via 112 formed within the dielectric layer 106 such that the via 112 is substantially above the center of the bottom electrode 104. In one embodiment of the invention the bottom of the via 112 is the top surface of the bottom electrode 104. Those skilled in the art will recognize that various methods may be employed to from the via 112. An example of such a method with be photolithography followed by reactive ion etching

Now turning to FIG. 2, a stress liner material 202 is deposited along at least one sidewall and the bottom of the via 112, and above the dielectric layer 106. The stress liner material 202 imparts stress on material proximate the stress liner material 202. In one embodiment of the invention the stress liner material 202 has a thickness in the range of 5 to 100 nanometers. The stress liner material 202 may be comprised of a variety of materials such as tensile silicon nitride and compressive silicon nitride. In one particular embodiment of the invention the stress liner material 202 is comprised of at least one of SiO₂, SiN, SiCOH, TiO₂ and Ta₂O₅.

In one embodiment of the invention, the stress liner material 202 provides a stress in the range of 500 to 5000 MPa on the material enclosed within its volume. In a phase change memory configuration contemplated by the present invention, the material enclosed by the stress liner material 202 is phase change material. As an example, germanium-antimony-tellurium (GST) melts at room temperature under 20 GPa of pressure. Those skilled in the art will appreciate that the increased pressure imparted by the stress liner material 202 coupled with pressure involved with thermal expansion of GST effectively lowers the melting point of GST. Additionally, as stated above, the lower melting point also results in a larger melt region.

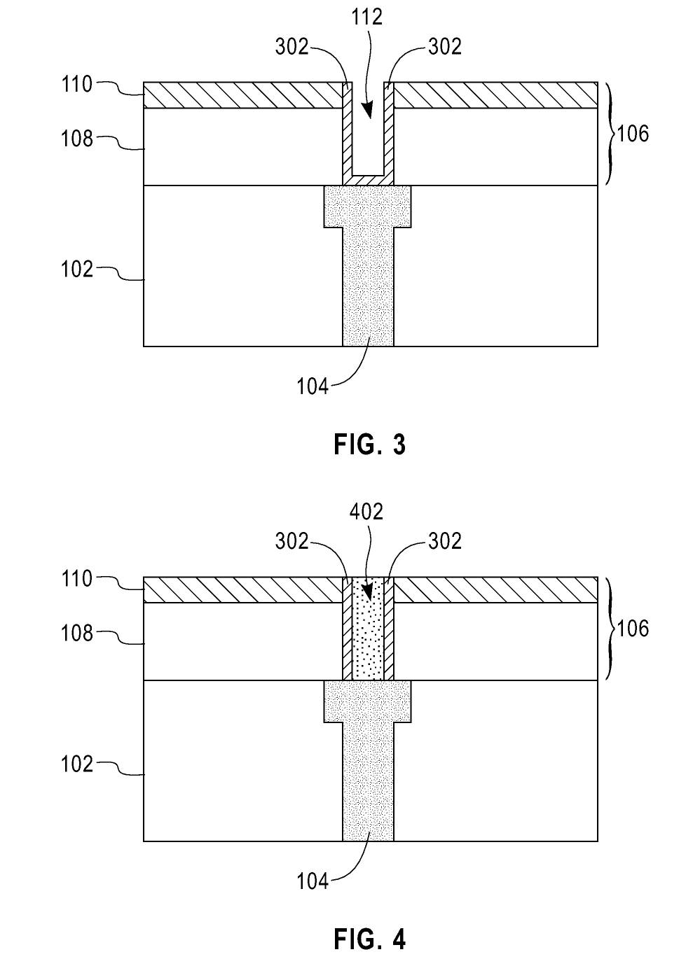

FIG. 3 illustrates an etch performed on the stress liner material. The etch removes the stress liner material from the bottom of the via 112 and top surface of the dielectric layer 106. Those skilled in the art will recognize that a variety of etches may be utilized for the etch, such as a spacer reactive-ion etch (RIE). The result is a stress liner 302 that is formed along at least one sidewall of the via 112.

Now turning to FIG. 4, the phase change material 402 is deposited in the via and polished using a Chemical Mechanical Polishing (CMP) process and within the volume enclosed by the stress liner 302. Those skilled in the art will recognize that the phase change material may be comprised of a variety of materials such as GST, AIST, etc.

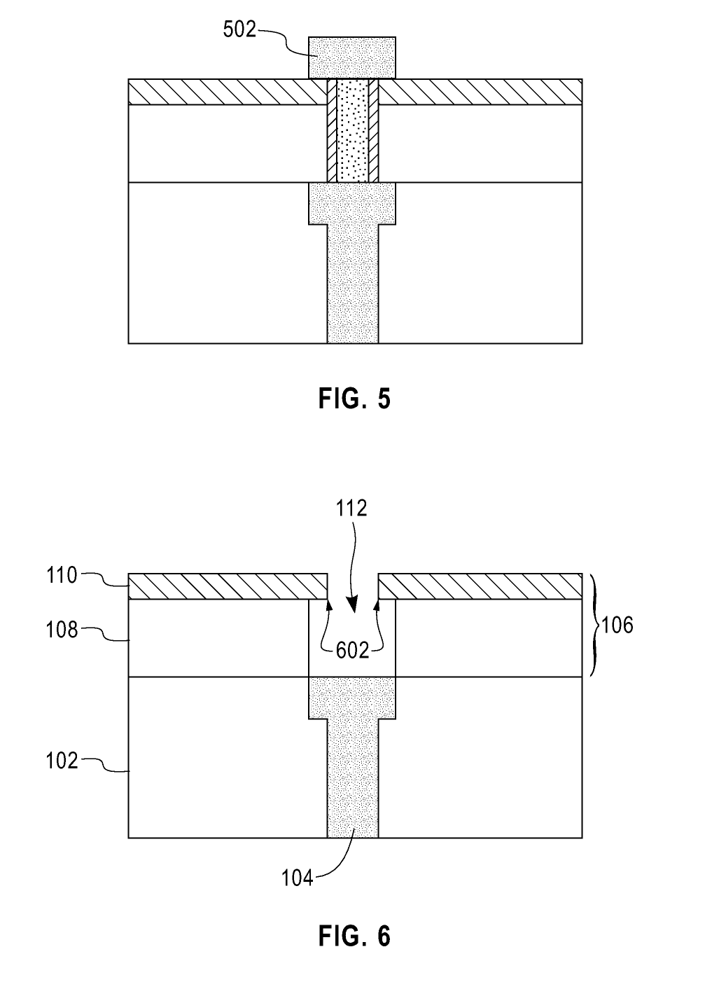

FIG. 5 illustrates forming a top electrode 502 in accordance with one embodiment of the invention. The top electrode 502 is comprised of an electrically conductive material such as titanium-nitride (TiN). Those skilled in the art will recognize a variety processes may be utilized in forming the top electrode 502 such as sputter deposition, photolithography and reactive ion etching.

FIGS. 6-10 illustrate an alternate embodiment of the method. FIG. 6 shows the substrate 102, the bottom electrode 104, the dielectric layer 106, and the via 112 of FIG. 1. FIG. 6 also shows the formation of an undercut 602 in the bottom dielectric layer 108 such that the top dielectric layer 110 overhangs the bottom dielectric layer 108. An etch is performed on the bottom dielectric layer 108 to form the undercut 602. Those skilled in the art will recognize a variety of etches maybe utilized such as a wet dilute hydrofluoric acid (DHF) etch.

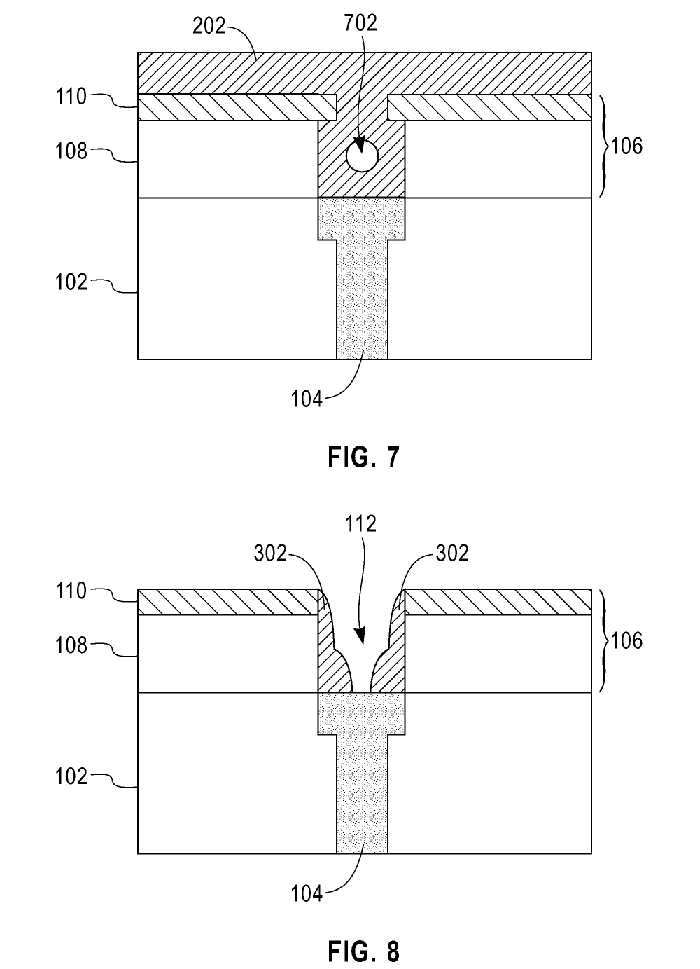

Now turning to FIG. 7, in accordance with one embodiment of the method, the stress liner material 202 is deposited in the via such that a cavity 702 is formed within the stress liner material 202 in the via. The diameter of the cavity 702 is approximately twice the size of the undercut. The stress liner material 202 utilized is conformal in accordance with this particular embodiment of the invention. As stated above, the stress liner material 202 may be comprised of a variety of materials such as tensile silicon nitride and compressive silicon nitride. In one particular embodiment of the invention the stress liner material 202 is comprised of at least one of SiO₂, SiN, SiCOH, TiO₂ and Ta₂O₅.

FIG. 8 shows an etching of the stress liner material such that the stress liner material forms the stress liner 302, with the stress liner 302 having a relatively large top aperture and a relatively small bottom aperture. Thus, the thickness of the stress liner is non-uniform along a length of the via, which causes the stress imparted by the stress liner to be non-uniform along a length of the via. Those skilled in the art will recognize that a variety of etches may be performed such as a directional stress liner RIE.

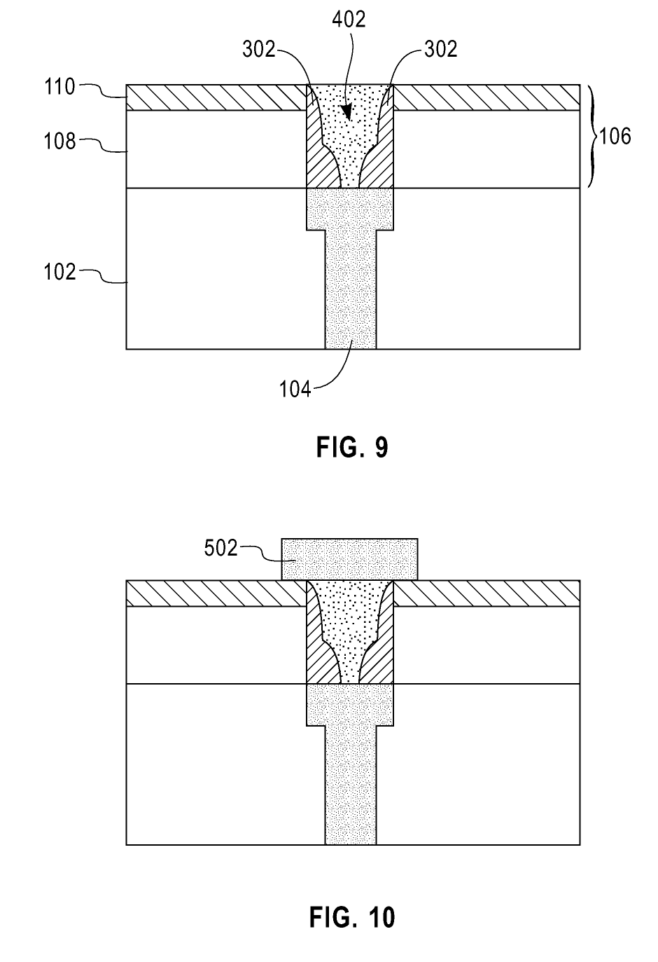

Now turning to FIG. 9, the phase change material 402 is deposited in the via and polished using a Chemical Mechanical Polishing (CMP) process and within the volume enclosed by the stress liner 302. As stated above, those skilled in the art will recognize that the phase change material may be comprised of a variety of materials such as GST, AIST, etc.

FIG. 10 illustrates the formation of the top electrode 502 in accordance with one embodiment of the invention. The top electrode 502 is comprised of an electrically conductive material, such as TiN. Those skilled in the art will recognize a variety processes may be utilized in forming the top electrode 502 such as sputter deposition.

Having described preferred embodiments for the method for forming a memory cell structure (which are intended to be illustrative and not limiting), it is noted that modifications and variations can be made by persons skilled in the art in light of the above teachings. It is therefore to be understood that changes may be made in the particular embodiments disclosed which are within the scope and spirit of the invention as outlined by the appended claims. Having thus described aspects of the invention, with the details and particularity required by the patent laws, what is claimed and desired protected by Letters Patent is set forth in the appended claims.

What is claimed is:

1. A method for forming a memory cell structure, the method comprising:
forming a bottom electrode within a substrate, the bottom electrode being electrically conducting;
depositing a dielectric layer over the bottom electrode, the dielectric layer being electrically insulating;
forming a via within the dielectric layer and substantially over the center of the bottom electrode, the via including at least one sidewall;
depositing a stress liner along the at least one sidewall of the via such that the stress liner imparts stress on material proximate the stress liner;
depositing a phase change material within the via and a volume enclosed by the stress liner; and
forming a top electrode above the phase change material, the top electrode being electrically conducting.

2. The method of claim 1, wherein the stress liner comprises compressive Silicon Nitride.

3. The method of claim 1, wherein the stress liner comprises tensile Silicon Nitride.

4. The method of claim 1, wherein the stress liner comprises at least one of SiO₂, SiN, SiCOH, TiO₂ and Ta₂O₅.

5. The method of claim 1, wherein the dielectric layer is comprised of at least two separately removable layers such that there is a top dielectric layer formed above a bottom dielectric layer.

6. The method of claim 5, wherein depositing the stress liner further comprises:
forming an undercut in the bottom dielectric layer such that the top dielectric layer overhangs the bottom dielectric layer;
depositing a stress liner material in the via such that a cavity is formed within the stress liner material in the via; and
etching the stress liner material such that the stress liner material forms the stress liner, the stress liner having a relatively large top aperture and a relatively small bottom aperture.

7. The method of claim 1, further comprising etching the stress liner such that a thickness of the stress liner is non-uniform along a length of the via.

8. The method of claim 1, further comprising etching the stress liner such that the stress imparted by the stress liner is non-uniform along a length of the via.

9. The method of claim 1, wherein the stress liner has a thickness in the range of 5 nanometers to 100 nanometers.

10. The method of claim 1, wherein the stress liner provides a stress in the range of 500 MPa to 5000 MPa on the material enclosed within its volume.

11. A memory cell structure comprising:
an electrically conducting bottom electrode;
a stress liner forming a via above the bottom electrode, the stress liner imparting stress on material within the via;
a phase change material disposed within the via and a volume enclosed by the stress liner; and
an electrically conducting top electrode disposed above the phase change material.

12. The memory cell structure of claim 11, wherein the stress liner comprises tensile Silicon Nitride.

13. The memory cell structure of claim 11, wherein the stress liner comprises compressive Silicon Nitride.

14. The memory cell structure of claim 11, wherein the stress liner comprises at least one of SiO₂, SiN, SiCOH, TiO₂ and Ta₂O₅.

15. The memory cell structure of claim 11, wherein a thickness of the stress liner is non-uniform along a length of the via.

16. The memory cell structure of claim 11, wherein the stress imparted by the stress liner is non-uniform along a length of the via.

17. The memory cell structure of claim 11, wherein the stress liner has a thickness in the range of 5 nanometers to 100 nanometers.

18. The memory cell structure of claim 11, wherein the stress liner provides a stress in the range of 500 MPa to 5000 MPa on the material enclosed within its volume.

19. The memory cell structure of claim 11, further comprises a dielectric layer, the dielectric layer being dielectric.
